(19) United States
(12) Patent Application Publication
(10) Pub. No.: US 2008/0064227 A1
(43) Pub. Date: Mar. 13, 2008

(54) Apparatus For Chemical Vapor Deposition and Method For Cleaning Injector Included in the Apparatus

(76) Inventor: Jin-Sung KIM, Hwaseong-si (KR)

Correspondence Address: Frank Chau, Esq.;F. CHAU & ASSOCIATES, LLC, 130 Woodbury Road,, Woodbury, NY, 11797, US

(21) Appl. No.: 11/762,950

(22) Filed: Jun. 14, 2007

(30) Foreign Application Priority Data
Sep. 7, 2006 (KR) 2006-0085956

(51) Int. Cl. H01L 21/443; C23C 16/00

(52) U.S. Cl. 438/787; 118/708; 118/710; 118/715; 118/728; 257/E21.477

(57) ABSTRACT

An apparatus for chemical vapor deposition includes a reaction chamber providing a predetermined sealed space, a reaction gas supply unit for supplying a first reaction gas into the reaction chamber and a reaction gas supply line formed by operatively connecting the reaction gas supply unit and the reaction chamber. The reaction gas supply line allows the first reaction gas to flow through. The apparatus further includes a raw material supply unit for supplying at least one liquid raw material for generating a second reaction gas to be mixed with the first reaction gas supplied through the reaction gas supply line, a liquid raw material supply line allowing the at least one liquid raw material, which is supplied from the raw material supply unit, to flow into the reaction gas supply line, an injector for injecting the at least one liquid raw material to be vaporized at a portion where the liquid raw material supply line is connected to the reaction gas supply line. Moreover, the apparatus further includes a cleaning module for cleaning the injector by removing precipitates which are precipitated as the at least one liquid raw material is attached to and embedded in an inner wall of the injector or the at least one liquid raw material vaporized in the injector is chemically combined with the first reaction gas.

### CROSS-REFERENCE TO RELATED APPLICATION

This application claims the benefit of Korean Patent Application No. 10-2006-0085956, filed Sep. 7, 2006, the disclosure of which is hereby incorporated herein by reference in its entirety.

### BACKGROUND OF THE INVENTION

1. Technical Field

The present disclosure relates to an apparatus for fabricating a semiconductor device, and more particularly, to an apparatus for chemical vapor deposition (CVD), which forms a predetermined thin film on a wafer by a chemical vapor deposition process, and to a method for cleaning an injector included in the same apparatus.

2. Discussion of Related Art

In an effort to increase the operational speed of a semiconductor chip and to increase the information storage capacity per unit area, the semiconductor device fabricating industry has reduced the minimum critical dimensions to be applied for a semiconductor integrated circuit process. For example, the dimensions of a semiconductor device, such as a transistor integrated on a semiconductor wafer, have been reduced to about a sub-half micron or less.

A semiconductor device is fabricated through a deposition process, a photolithography process, an etch process and a diffusion process. These processes are repeated several times to several tens of times, thereby fabricating at least one semiconductor apparatus. For example, processes such as a deposition process to form a processing layer on a wafer, by a sol-gel process, a sputtering process, an electro-plating process, an evaporation process, a chemical vapor deposition process, a molecule beam epitaxy process, and an atomic layer deposition process are used for improving the reproducibility and reliability of fabricating a semiconductor device.

Among the aforementioned processes, the chemical vapor deposition process is most generally used because of its relatively high deposition characteristics including the step coverage and uniformity of a thin film formed on a wafer, and high productivity, compared to the other deposition processes. The chemical vapor deposition process includes a low pressure chemical vapor deposition (LPCVD), atmospheric pressure chemical vapor deposition (APCVD), low temperature chemical vapor deposition (LTCVD) and plasma enhanced chemical vapor deposition (PECVD).

For example, the PECVD is a process of forming a dielectric layer, by depositing, on a wafer, a material produced as a result of making a chemical reaction in a gas through electric discharge. In a conventional PECVD process, after a number of wafers are put inside the apparatus for plasma chemical vapor deposition, the PECVD process is performed in a batch mode, thereby forming a specific layer on the number of wafers. However, as the tendency in the semiconductor industry is towards providing semiconductor devices with high integration and wafer with large diameter, the PECVD process is performed after one sheet of a wafer is put inside the apparatus for plasma chemical vapor deposition. After the PECVD process of one sheet of the wafer is finished, a cleaning and purge process is performed to remove the residual gases and reaction products which are present inside the apparatus for plasma chemical vapor deposition.

The chemical vapor deposition process, such as the PECVD process, is performed such that a predetermined material layer is deposited on a wafer through a chemical reaction, by allowing raw materials in a gaseous state to flow into a reaction chamber.

The raw materials being gaseous are directly supplied to a reactor. However, the raw materials being condensed to a liquid at a room temperature are supplied to a shower head of the reaction chamber after vaporizing the raw materials through a bubbling process, a vapor flow control process, a liquid delivery process or an injection process.

For example, in the environment of room temperature or a temperature close to room temperature and an activated gas such as oxygen (O₂) which has predetermined pressure being lower than normal pressure, the injection process is to inject liquid raw materials at considerably higher pressure, compared to the pressure of the activated gas, so that the liquid raw materials are vaporized for being supplied to the shower head of the reaction chamber. The liquid raw materials react to the activated gas such as oxygen, to be vaporized by the injecting pressure.

Conventional equipment and methods for chemical vapor deposition using the injection process are described in U.S. Pat. Nos. 5,928,428 and 6,235,112.

However, the conventional equipment for chemical vapor deposition may have the following difficulties set forth below associated therewith. For instance, with the conventional equipment for chemical vapor deposition, as a predetermined time for use passes, an injector for injecting the liquid raw materials to be vaporized is frequently clogged with precipitates derived when the liquid raw materials are attached and embedded inside the injector or when the liquid raw materials injected from the injector are chemically combined with a reaction gas, such as oxygen being the activated gas. Consequently, as the period of replacing the injector is shortened, the productivity decreases.

### SUMMARY OF THE INVENTION

Therefore, the exemplary embodiments of the present invention is directed to provide an apparatus for chemical vapor deposition and to a method for cleaning an injector included in the apparatus, which prevent liquid raw materials from being attached and embedded inside the injector as a time for use passes and which prevent the injector from being clogged with precipitates derived from the chemical combination of the liquid raw materials injected from the injector and a reaction gas, thereby extending a period of replacing the injector, to increase or maximize the productivity.

In accordance with an exemplary embodiment of the present invention an apparatus for chemical vapor deposition is provided. The apparatus includes a reaction chamber providing a predetermined sealed space, a reaction gas supply unit for supplying a first reaction gas into the reaction chamber and a reaction gas supply line formed by connect the reaction gas supply unit and the reaction chamber. The reaction gas supply line allows the first reaction gas to flow through. The apparatus further includes a raw material supply unit for supplying at least one liquid raw material for generating a second reaction gas to be mixed with the first reaction gas supplied through the reaction gas supply line, a liquid raw material supply line allowing the at least one liquid raw material, which is supplied from the raw material supply unit, to flow into the reaction gas supply line, an injector for injecting the at least one liquid raw material to be vaporized at a portion where the liquid raw material supply line is connected to the reaction gas supply line. In addition, the apparatus further includes a cleaning module for cleaning the injector by removing precipitates which are precipitated as the at least one liquid raw material is attached to and embedded in an inner wall of the injector or the at least one liquid raw material vaporized in the injector is chemically combined with the first reaction gas.

The cleaning module may include an inactivated gas supply unit for supplying an inactivated gas at predetermined pressure; an inactivated gas supply line allowing the inactivated gas supplied from the inactivated gas supply unit to flow through and an LSU valve positioned at the end of the inactivated gas supply line corresponding to the inactivated gas supply unit. The LSU valve controls the liquid raw materials being supplied form the liquid raw material supply unit or the inactivated gas so as to be selectively supplied to the injector. Also, the LSU valve may be a three-way valve so that the at least one liquid raw material and the inactivated gas are selectively supplied through the injector and injected into the reaction gas supply line.

In accordance with another exemplary embodiment of the present invention, a method for cleaning an injector included in an apparatus for chemical vapor deposition is provided. The method includes loading a wafer inside a reaction chamber, forming a thin film of a predetermined thickness on the wafer, by supplying a first reaction gas and a second reaction gas into the reaction chamber while pumping the air present inside the reaction chamber. The method further includes stopping the supply of the first reaction gas and the second reaction gas and unloading the wafer to the outside of the reaction chamber after forming the thin film of the predetermined thickness on the wafer, determining the number of the wafers on which the thin film is formed inside the reaction chamber and cleaning an injector, by supplying a purge gas into the reaction chamber and supplying an inactivated gas into the injector which injects at least one liquid raw material used as the second reaction gas supplied into the reaction chamber after the wafers on which the thin film is formed reach a predetermined number.

### BRIEF DESCRIPTION OF THE DRAWINGS

Exemplary embodiments of the present invention can be understood in more detail from the following detailed description taken in conjunction with the attached drawings in which:

FIG. 1 is a schematic diagram illustrating apparatus for chemical vapor deposition, according to an exemplary embodiment of the present invention;

FIG. 2 is a diagram illustrating a tetraethoxysilane (TEOS) supply unit and a cleaning module of FIG. 1; and

FIG. 3 is a flow chart illustrating a method for cleaning an injector, according to an exemplary embodiment of the present invention.

### DETAILED DESCRIPTION OF THE EXEMPLARY EMBODIMENTS OF THE INVENTION

The exemplary embodiments of the present invention will now be described more fully hereinafter with reference to the accompanying drawings, in which exemplary embodiments of the invention are shown. This invention may, however, be embodied in many different forms and should not be construed as being limited to the embodiments set forth herein. In the drawings, the shapes of elements are exaggerated for clarity.

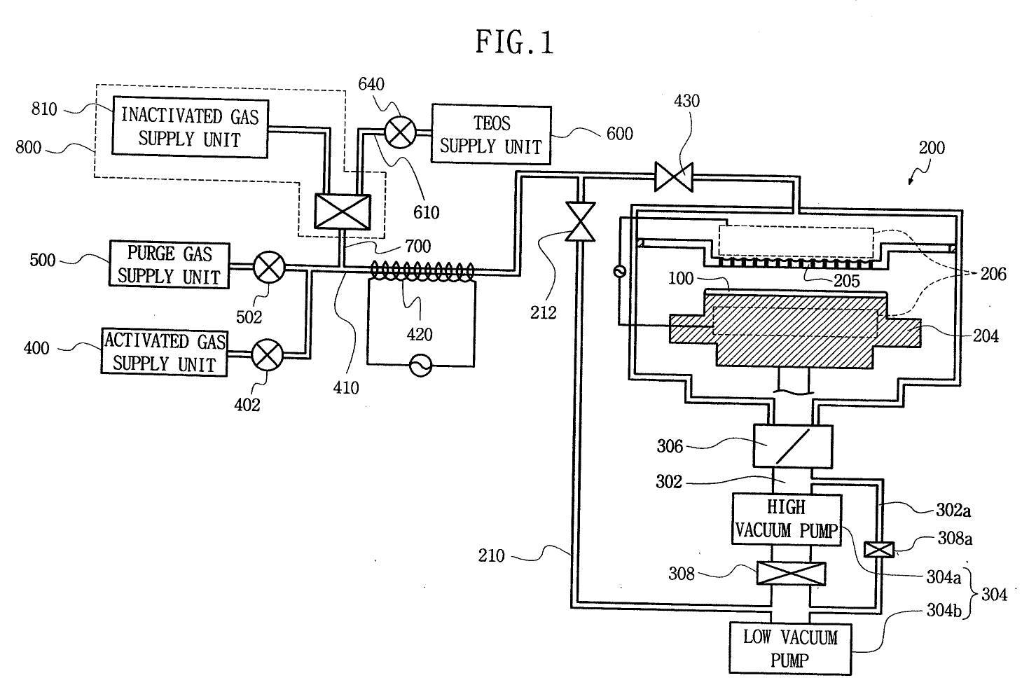

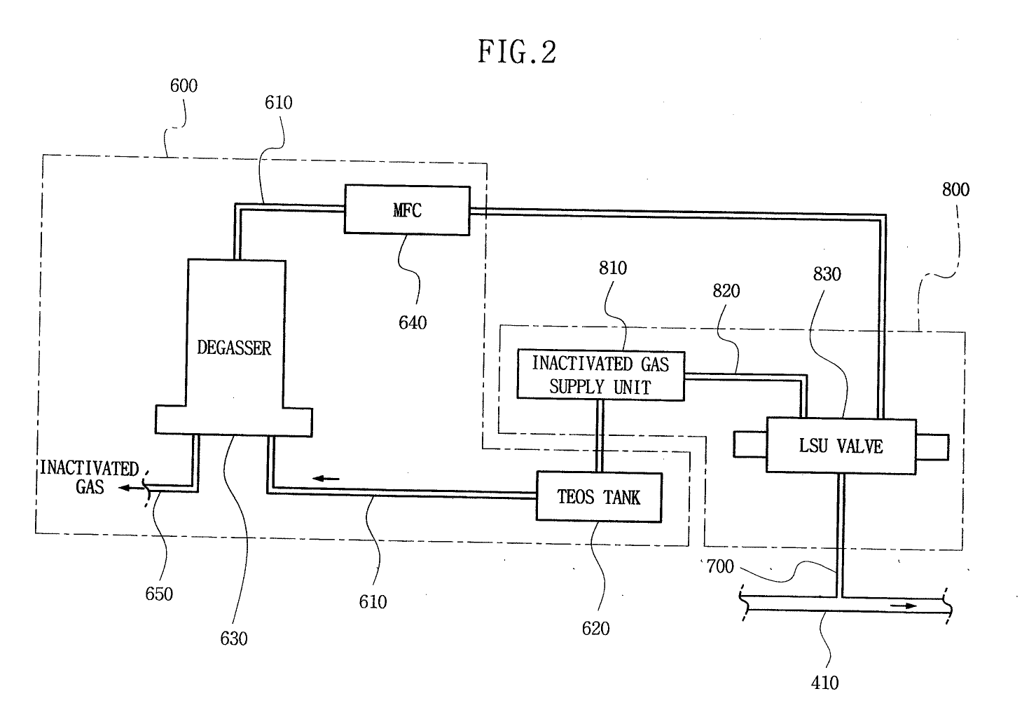

FIG. 1 is a schematic diagram illustrating apparatus for chemical vapor deposition, according to an exemplary embodiment of the present invention, and FIG. 2 is a diagram illustrating a tetraethoxysilane (TEOS) supply unit and a cleaning module of FIG. 1.

As illustrated in FIG. 1, the apparatus for chemical vapor deposition comprises: a reaction chamber 200, an activated gas supply unit 400, a reaction gas supply line 410, a TEOS supply unit 600 (for example, liquid raw material supply unit), a liquid raw material supply line 610, an injector 700, and a cleaning module 800. The reaction chamber 200 provides a predetermined space which is sealed from the air, to form a thin film, such as a TEOS layer, on a wafer 100. The activated gas supply unit 400 supplies an activated gas (for example, a first reaction gas), such as, for example, oxygen or ozone, to the inside of the reaction chamber 200. The reaction gas supply line 410 operatively connects the activated gas supply unit 400 to the reaction chamber 200, for flow of the activated gas. The TEOS supply unit 600 (for example, the liquid raw material supply unit) supplies a TEOS liquid (for example, a liquid raw material) used as a raw material to generate a TEOS gas (for example, a second reaction gas) which is a precursor to be mixed with the activated gas being supplied through the reaction gas supply line 410. The liquid raw material supply line 610 is formed to allow the TEOS liquid being supplied from the TEOS supply unit 600 to flow into the reaction gas supply line 410. The injector 700 injects the TEOS liquid to be vaporized to the TEOS gas, at the position where the liquid raw material supply line 610 is connected to the reaction gas supply line 410. The cleaning module 800 is formed to clean the injector 700 by removing the TEOS liquid being attached to and embedded in an inside wall of the injector 700 or by removing, from the injector 700, the precipitates derived from the chemical combination of the TEOS gas and the activated gas.

The apparatus for chemical vapor deposition further comprises a cleaning gas supply unit for supplying a cleaning gas to the reaction gas supply line 410, wherein the cleaning gas cleans the inside of the reaction chamber 200 by removing the deposit being deposited in the reaction chamber 200.

In the reaction chamber 200, a uniform TEOS thin film is formed on the wafer 100, by, for example, a chemical vapor deposition process using the TEOS gas and the activated gas supplied through the reaction gas supply line 410. For example, the reaction chamber 200 comprises a shower head 205, a chuck 204, and at least one upper plasma electrode 206 and at least one lower plasma electrode 206. The shower head 205 sprays the activated gas and the TEOS gas at an upper portion of the reaction chamber 200 under the reaction gas supply line 410. The chuck 204 supports the wafer 100 horizontally at a lower portion of the reaction chamber 200, facing the shower head 205. The at least one upper plasma electrode 206 is formed above the shower head 205 and the at least one lower plasma electrode 206 is formed under the chuck 204. When high frequency power is externally applied to the upper and lower plasma electrodes, the TEOS gas and the activated gas are plasmatized between the shower head 205 and the wafer 100 on the chuck 204. Accordingly, the reaction chamber 200 forms the TEOS thin film of a predetermined thickness on the wafer 100 on the chuck 204, by allowing the activated gas and TEOS gas sprayed through the shower head 205 to flow above the wafer 100.

Then, the activated gas and TEOS gas, used to form the TEOS thin film on the wafer 100, should consistently flow, at the uniform flow rate, above the wafer 100. The reaction chamber 200 should maintain a constant pressure to form the TEOS thin film reproducibly. The remaining activated gas and TEOS gas after forming the TEOS thin film on the wafer 100 should be continuously exhausted to the outside of the reaction chamber 200.

Accordingly, in the reaction chamber 200, the activated gas and TEOS gas are pumped by a vacuum pump 304 operatively connected to an exhaust line 302. A vacuum gauge is positioned at the reaction chamber 200 or the exhaust line 302, to measure the degree of a vacuum inside the reaction chamber 200 in which the activated gas and TEOS gas are pumped by the vacuum pump 304. For example, the vacuum pump 304 includes a high vacuum pump 304a, such as, for example, a turbo pump or a diffusion pump, and a low vacuum pump 304b, such as a dry pump or a rotary pump which is connected in series to the foreline of a rear end of the high vacuum pump. At the foreline, a foreline valve 308 is formed to control the pumping of the high vacuum pump 304a. A roughing line 302a, which is divided from the exhaust line 302 of a front end of the high vacuum pump 304a, is connected in parallel to the exhaust line 302 of a front end of the low vacuum pump 304b, bypassing the high vacuum pump 304a. A roughing valve 308a is formed to control the pumping of the low vacuum pump 304b through the roughing line 302a. At a rear end of the low vacuum pump 304b, a scrubber is formed to purge the exhaust gases, such as the activated gas and the TEOS gas, which are exhausted through the exhaust line 302 by the low vacuum pump 304b, to be discharged in the air. When the roughing valve 308a is operated to be open, the foreline valve 308 is operated to be closed, and vice versa. Accordingly, upon pumping the air present inside the reaction chamber 200 to reach a predetermined degree of a vacuum, the foreline valve 308 is closed and the roughing valve is opened so that the low vacuum pump 304b pumps. Then, when the inside of the reaction chamber 200 is in a low vacuum state, the roughing valve 308a is closed and the foreline valve 308 is opened so that the high vacuum pump 304a pumps, in high-vacuum, the inside of the reaction chamber 200. For example, when the wafer 100 is loaded on the chuck 204 in the reaction chamber 200, the inside of the reaction chamber 200 is pumped to be in a high vacuum state of about 1×10⁻⁶ torr, and then it is set to be maintained in a low vacuum state of about 4×10⁻³ torr. While the reaction chamber 200 is maintained in the low vacuum state, the activated gas and TEOS gas are supplied to form the uniform TEOS thin film on the wafer 100. Thus, the apparatus for chemical vapor deposition in accordance with exemplary embodiments of the present invention comprises an pressure control valve 306 which is positioned at the exhaust line 302 in the front end of the vacuum pump 304 and controls the amount of the exhaust gases, such as the activated gas and the TEOS gas being pumped by the vacuum pump 304, to maintain the pressure of vacuum inside the reaction chamber 200.

The apparatus for chemical vapor deposition in accordance with exemplary embodiments of the present invention further comprises a purge gas supply unit 500. The purge gas supply unit 500 is positioned at the end of the reaction gas supply unit 410 connected to the reaction chamber 200, thereby supplying a purge gas, such as, for example, nitrogen, onto the wafer 100 positioned on the chuck 204 in the reaction chamber 200 before and after the activated gas or TEOS gas is supplied. The purge gas supplied from the purge gas supply unit 500 flows into the reaction gas supply line 410 and cleans the precipitates which are precipitated inside the reaction gas supply line 410. A heater block 420 is formed at the outer circumferential surface of the reaction gas supply line 410 and prevents the activated gas and TEOS gas flowing through the reaction gas supply line 410 from forming precipitates. For example, the activated gas and TEOS gas are heated at a high temperature of about 120° C. by the heat generated from the heater block 420, to be supplied into the reaction chamber 200. The activated gas supplied from the activated gas supply unit 400 and the TEOS gas supplied from the TEOS supply unit 600 are vaporized in the injector 700, mixed and flow through the reaction gas supply line 410. These gases are then heated by the heat of the heater block 420 and supplied to the shower head 205 of the reaction chamber 200, without forming the precipitates on the inner wall of the reaction gas supply line 410.

The apparatus for chemical vapor deposition in accordance with exemplary embodiments of the present invention may further comprise a gas mixing chamber which is positioned at the reaction gas supply line 410 connected between the injector 700 and the shower head 205 and mixes the activated gas and the TEOS gas in the uniform mixture ratio.

A dump line 210, which is divided from the reaction gas supply line 410 connected between the injector 700 and the shower head 205, is formed to be connected to the foreline, bypassing the reaction chamber 200. Before the TEOS thin film is deposited on the wafer 100 in the reaction chamber 200, the dump line 210 allows the activated gas and TEOS gas, which are supplied through the reaction gas supply line 410, not to be supplied into the reaction chamber 200 but to be exhausted through the exhaust line 302. A dump valve 212 is positioned at the dump line 210 and controls the flow of the activated gas and TEOS gas being exhausted to the exhaust line 302 through the dump line 210. For example, the reaction gas supply line 410 and the dump line 210 are formed to have an inner diameter of about 14 inches.

The activated gas supply unit 400 and the purge gas supply unit 500 are capable of vaporizing, for example, liquid oxygen or nitrogen to an activated gas or gaseous nitrogen having predetermined pressure to be supplied to the reaction gas supply line 410. The oxygen and nitrogen are gaseous at a room temperature but they are liquid in a tank with the pressure of several hundred atmosphere (atm) or higher. Accordingly, the activated gas supply unit 400 and the purge gas supply unit 500 respectively include a decompression valve. A first flow controller 402 is positioned at the reaction gas supply line 410 connected to a rear end of the activated gas supply unit 400, and a second flow controller 502 is positioned at the reaction gas supply line 410 connected to a rear end of the purge gas supply unit 500. At the reaction gas supply line 410 in the front and back of the first flow controller 402 and second flow controller 502, an activated gas supply valve and a purge gas supply valve may be formed to control the supply of the activated gas and the purge gas, respectively.

The TEOS supply unit 600 supplies the TEOS liquid through the liquid raw material supply line 610, using the flow pressure of an inactivated gas, such as, for example, helium (He), being supplied from an inactivated gas supply unit 810 (of FIG. 2) of the cleaning module 800.

As illustrated in FIG. 2, the TEOS supply unit 600 comprises a TEOS tank 620, a degasser 630, and a third flow controller 640. The TEOS tank 620 stores the TEOS liquid and sends the TEOS liquid, together with the inactivated gas supplied from the inactivated gas supply unit 810. The degasser 630 separately extracts the activated gas from the mixture of the TEOS liquid and the inactivated gas which are sent from the TEOS tank 620 and discharges the activated gas to the outside. The third flow controller 640 controls the flow rate of the TEOS liquid which is separated in the degasser 630 and is flowed into the liquid raw material supply line 610. A third control valve is further included between the degasser 630 and the third flow controller 640 and controls the supply of the TEOS liquid which flows through the liquid raw material supply line 610.

The TEOS tank 620 is formed to receive a TEOS container, such as, for example, a bottle or a case, in which a TEOS liquid source is positioned. The TEOS tank 620 sends the TEOS liquid source to the degasser 630, using the predetermined pressure of the inactivated gas being supplied from the inactivated gas supply unit 810.

The degasser 630 separately extracts the TEOS liquid, using the difference between the density of the TEOS liquid and the inactivated gas which are sent from the TEOS tank 620. For example, as the TEOS liquid which is higher in density compared to the inactivated gas has higher gravity, the TEOS liquid is collected downward in a predetermined sealed container by gravity. Accordingly, the degasser 630 selectively and separately extracts the TEOS liquid through an entrance of the liquid raw material supply line 610 connected to the bottom of the container where the TEOS liquid is collected downwardly. The degasser 630 also discharges the inactivated gas through an inactivated gas discharge pipe 650 connected to the top of the container.

The third flow controller 640 controls the flow rate of the TEOS liquid which flows through the liquid raw material supply line 610, so that the activated gas supplied from the activated gas supply unit 400 and the TEOS gas injected and vaporized in the injector 700 have the regular mixture ratio. The third flow controller 640 and the first flow controller are operatively connected and controlled by a control signal being output from a controller of the apparatus for chemical vapor deposition.

The liquid raw material supply line 610 through which the TEOS liquid flows is formed to have a smaller inner diameter, compared to the reaction gas supply line 410 through which the mixture of the TEOS gas and the activated gas flows. For example, the liquid raw material supply line 610, through which the TEOS liquid flows, is formed of a metal material with a plastic material of high corrosion resistance coated on its inner surface, and has an inner diameter of about ⅛ inches.

The injector 700 for vaporizing the TEOS liquid, positioned at the end of the liquid raw material supply line 610, is an injection line or a vaporizer having the same inner diameter as the liquid raw material supply line 610. The injector 700 is connected to the reaction gas supply line 410 between the reaction gas supply unit and the dump line 210. For example, the injector 700 includes a linear nozzle for injecting the TEOS liquid, which is supplied to the liquid raw material supply line 610, into the reaction gas supply line 410. The injector 700 is extended from the end of the liquid raw material supply line 610 and is connected to the reaction gas supply line 410. The injector 700 injects the TEOS liquid, which is supplied at high pressure through the liquid raw material supply line 610, into the reaction gas supply line 410, thereby vaporizing the TEOS liquid. The TEOS liquid being injected and vaporized in the injector 700 absorbs the evaporation heat, thereby cooling the injector 700. Accordingly, as the evaporation heat is absorbed, the TEOS liquid which flows into the injector 700 is cooled and condensed to be precipitated inside the injector 700, thereby deteriorating the performance of the injector 700. Moreover, as the TEOS liquid being injected in the injector 700 reacts to the activated gas, the TEOS liquid is cohered at a tip of the injector 700, thereby forming the precipitates. These precipitates interrupt the subsequent injection of the TEOS liquid and clog the tip of the injector 700, thereby causing a failure of chemical vapor deposition. Thus, the apparatus for chemical vapor deposition in accordance with exemplary embodiments of the present invention includes the cleaning module 800 for cleaning the injector 700 so that the precipitates being precipitated in the injector 700 are cleaned, thereby extending the life of use of the injector 700.

The cleaning module 800 comprises an inactivated gas supply unit 810, an inactivated gas supply line 820, and an LSU valve 830. The inactivated gas supply unit 810 supplies an inactivated gas, such as, for example, helium, at predetermined pressure. The inactivated gas supply line 820 conveys the inactivated gas supplied from the inactivated gas supply unit 810. The LSU valve 830 is positioned at the end of the inactivated gas supply line 820 corresponding to the inactivated gas supply unit 810 and controls so that the TEOS liquid supplied from the TEOS supply unit 600 or the inactivated gas is selectively supplied to the injector 700.

The inactivated gas supply unit 810 is formed to supply the inactivated gas to not only the injector 700 but also the TEOS tank 620. The inactivated gas supply unit 810 includes a helium storage tank and a decompression device. The helium storage tank stores the helium liquid having high pressure at a room temperature or low temperature. The decompression device buffers the pressure of the helium gas being vaporized in the helium storage tank, thereby supplying the helium gas to the inactivated gas supply line 820. The inactivated gas supply line 820 connected to the decompression device may be divided in parallel from the inactivated gas supply unit 810, to be connected to the LSU valve 830 or the TEOS tank 620.

When the TEOS thin film is deposited on the wafer 100 in the reaction chamber 200, the LSU valve 830 allows the TEOS liquid to flow into the injector 700. When the process of forming the TEOS thin film is completed in the reaction chamber 200, the LSU valve 830 allows the inactivated gas to flow into the injector 700. For example, the LSU valve 830 includes a three-way valve which allows the TEOS liquid and the inactivated gas to selectively flow through the injector 700.

Then, when the purge gas is supplied from the purge gas supply unit 500 to the reaction gas supply line 410, the controller controls so that the inactivated gas is supplied from the inactivated gas supply line 820 of the cleaning module 800 to the injector 700. For example, to clean the reaction chamber 200 after the TEOS thin film is formed on a predetermined number of wafers 100, a full flush process is performed to fill the inside of the reaction chamber 200 with the pure purge gas. Whenever the full flush process is performed, the controller outputs a control signal, so that the purge gas supplied from the purge gas supply unit 500 and the inactivated gas of the cleaning module 800 are supplied to the injector 700, to clean the injector 700.

The cleaning module 800 for cleaning the injector 700 through which the TEOS liquid flows prevents the liquid raw material from being attached to and embedded in the injector 700 as the time of using the injector 700 passes, or prevents the injector 700 from being clogged with the precipitates derived from the chemical combination of the liquid raw material being injected in the injector 700 and the reaction gas. Consequently, as the period of replacing the injector 700 is extended, the productivity is increased or maximized.

A method for cleaning the injector 700 included in the apparatus for chemical vapor deposition in accordance with exemplary embodiments of the present invention will be described below:

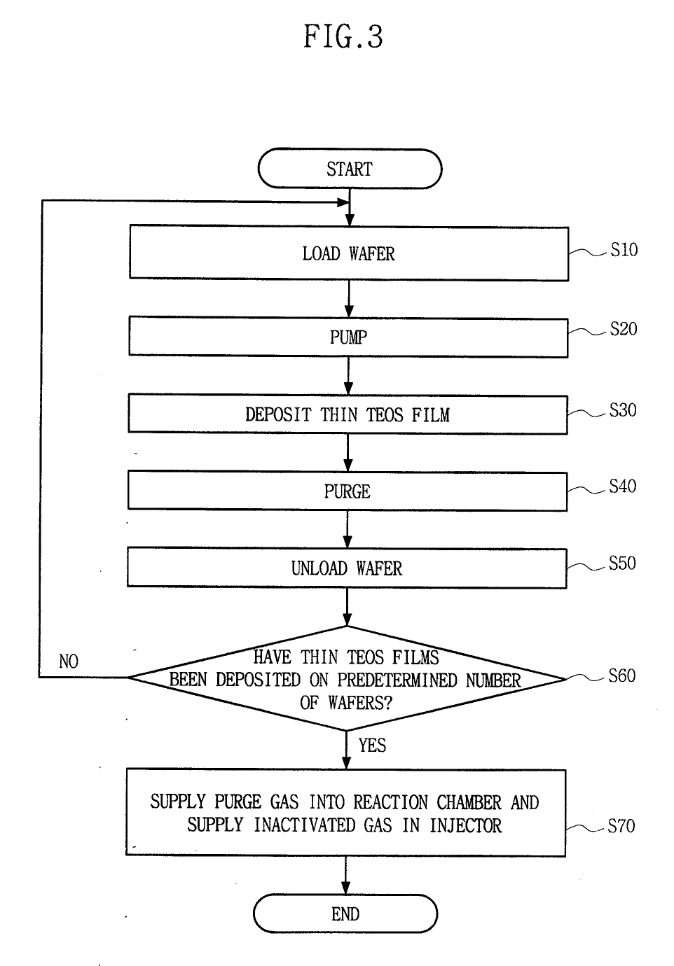

FIG. 3 is a flow chart illustrating the method for cleaning the injector 700, according to the present invention.

As illustrated in FIG. 3, when the chemical vapor deposition process of forming a TEOS thin film on a predetermined number of wafers 100 in the reaction chamber 200 is completed, the method for cleaning the injector 700 is to periodically clean the reaction chamber 200 and the injector 700, by supplying a purge gas into the reaction chamber 200 to clean the inside of the reaction chamber 200 and simultaneously supplying an activated gas into the injector 700 through which a TEOS liquid is injected.

A wafer 100 is loaded on a chuck 204 in the reaction chamber 200. For example, the wafer 100 is transferred to be loaded on the chuck 204, by a robot arm formed at a transfer chamber or a loadlock chamber which is operatively connected to the reaction chamber 200 (S10). A slit valve or a gate valve is formed between the reaction chamber 200 and the transfer chamber and is selectively opened when the robot arm enters or exits. Accordingly, when the robot arm exits from the reaction chamber 200 after the wafer 100 is loaded in the reaction chamber 200, the slit valve or gate valve is closed to seal the reaction chamber 200.

The vacuum pump 304 positioned at the exhaust line 302 operatively connected to the reaction chamber 200 pumps the air present inside the reaction chamber 200 (S20). The air present inside the reaction chamber 200 is pumped at a high vacuum of about 1×10⁻⁶ torr at the beginning of pumping and then is pumped at a low vacuum of about 1×10⁻³ torr before the TEOS thin film is formed on the wafer 100. As the purge gas is supplied from the purge gas supply unit 500, the reaction chamber 200 may be set to be in the low vacuum state. Further, the purge gas may be plasmatized before the TEOS thin film is formed inside the reaction chamber 200.

When the degree of a vacuum inside the reaction chamber 200 reaches a predetermined level, the TEOS gas and activated gas are respectively supplied from the TEOS gas supply unit and the activated gas supply unit 400 into the reaction chamber 200, thereby forming the TEOS thin film on the wafer 100 (S30). For example, when the TEOS gas and activated gas are respectively supplied into the reaction chamber 200 at the flow rate of about 50 standard cubic centimeters per minute (sccm) to about 200 sccm and the high frequency power of about 10 watts (W) to about 200 W is applied to the upper and lower plasma electrodes 206, the TEOS gas and activated gas are mixed in the plasma state, to form the uniform TEOS thin film on the wafer 100.

When the TEOS thin film of a predetermined thickness is formed on the wafer 100, the supply of the TEOS gas and activated gas to the reaction chamber 200 is stopped and the purge gas is supplied into the reaction chamber 200 (S40). The purge gas makes the TEOS gas and activated gas remaining inside the reaction chamber to be pumped by the vacuum pump 304 through the exhaust line 302.

The slit valve or gate valve positioned between the reaction chamber 200 and the transfer chamber is open so that the wafer on which the TEOS thin film is formed inside the reaction chamber 200 is unloaded to the outside of the reaction chamber 200 (S50). When the TEOS thin film is continuously formed on a number of wafers 100 sequentially inside the reaction chamber 200, contaminants, such as the TEOS thin film, remain on the inner wall of the reaction chamber 200 while the TEOS thin film is formed on the wafers 100. Thus, the cleaning process to remove the contaminants should be performed.

The controller checks the number of wafers 100 on which the TEOS thin film is formed and determines whether the wafers 100 on which the TEOS thin film is formed reach a predetermined number (S60). When the wafers 100 reach the predetermined number, the controller controls the cleaning process of the reaction chamber 200.

Upon the cleaning process, the wafers 100 are not loaded in the reaction chamber 200, and the purge gas and cleaning gas fill the inside of the reaction chamber 200. The purge gas and cleaning gas are plasmatized to remove the contaminants remaining on the inner wall of the reaction chamber 200. For example, the cleaning gas supplied from the cleaning gas supply unit includes nitrogen trifluoride (NF₃) gas.

Then, a full flush process is performed to completely remove the TEOS gas or activated gas remaining inside the reaction chamber 200, by supplying the purge gas into the reaction chamber 200. Upon the full flush process, the cleaning module 800 supplies the inactivated gas into the injector 700 through which the TEOS liquid is injected, to clean the injector 700 (S70). The inactivated gas supplied into the injector 700 may be discharged to the exhaust line 302, without flowing into the reaction chamber 200 through the reaction gas supply line 410 and the dump line 210.

The method for cleaning the injection 700 according to exemplary embodiments of the present invention supplies the inactivated gas to the injector 700, together with the purge gas supplied to the reaction chamber 200, upon the full flush process to clean the inside of the reaction chamber 200. Accordingly, the liquid raw material is prevented from being attached to and embedded inside the injector 700 as the time of use of the injector 700 passes, or the injector is prevented from being clogged with the precipitates derived from the chemical combination of the liquid raw material being injected in the injector 700 and the reaction gas. Consequently, as the period of replacing the injector 700 is extended, the productivity is increased or maximized.

As described above, in accordance with the apparatus for chemical vapor deposition comprising the cleaning module for cleaning the injector through which the TEOS liquid flows, the liquid raw material is prevented from being attached to and embedded inside the injector as the time of use of the injector passes, or the injector is prevented from being clogged with the precipitates derived from the chemical combination of the liquid raw material being injected in the injector and the reaction gas. Consequently, as the period of replacing the injector is extended, the productivity is increased or maximized.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. An apparatus for chemical vapor deposition comprising:
a reaction chamber providing a predetermined sealed space;
a reaction gas supply unit for supplying a first reaction gas into the reaction chamber;
a reaction gas supply line formed to connect the reaction gas supply unit and the reaction chamber, the reaction gas supply line allowing the first reaction gas to flow through;
a raw material supply unit for supplying at least one liquid raw material for generating a second reaction gas to be mixed with the first reaction gas supplied through the reaction gas supply line;
a liquid raw material supply line allowing the at least one liquid raw material, which is supplied from the raw material supply unit, to flow into the reaction gas supply line;
an injector for injecting the at least one liquid raw material to be vaporized at a portion where the liquid raw material supply line is connected to the reaction gas supply line; and
a cleaning module for cleaning the injector by removing precipitates which are precipitated as the at least one liquid raw material is attached to and embedded in an inner wall of the injector or the at least one liquid raw material vaporized in the injector is chemically combined with the first reaction gas.

2. The apparatus according to claim 1, wherein the reaction chamber comprises:
a shower head positioned at an upper position of the reaction chamber, the shower head for spraying the first reaction gas and the second reaction gas in an upper portion of the reaction chamber;
a chuck positioned at a lower position of the reaction chamber, facing the shower head, the chuck for supporting a wafer horizontally; and
at least one upper plasma electrode and at least one lower plasma electrode positioned above the shower head and under the chuck, respectively, the upper and lower plasma electrodes for plasmatizing the first reaction gas and the second reaction gas between the wafer on the chuck and the shower head, by high frequency power applied from the outside.

3. The apparatus according to claim 2, further comprising:
an exhaust line connected to a sidewall of the reaction chamber, adjacent to the chuck, the exhaust line for exhausting the first reaction gas and the second reaction gas inside the reaction chamber; and
a vacuum pump connected to an end of the exhaust line, facing the reaction chamber, the vacuum pump for pumping the first reaction gas and the second reaction gas after the reaction on the wafer inside the reaction chamber.

4. The apparatus according to claim 3, further comprising a dump line divided from the reaction gas supply line and connected to the exhaust line, bypassing the reaction chamber.

5. The apparatus according to claim 4, wherein the injector is connected to the reaction gas supply line between the reaction gas supply unit and the dump line.

6. The apparatus according to claim 1, further comprising: a purge gas supply unit for supplying a purge gas into the reaction chamber through the reaction gas supply line connected to the reaction chamber.

7. The apparatus according to claim 1, further comprising: a gas mixing chamber positioned at the reaction gas supply line connected between the injector and the reaction chamber, the gas mixing chamber for mixing the first reaction gas and the second reaction gas.

8. The apparatus according to claim 1, wherein the reaction gas supply line has an inner diameter of about ¼ inches and the liquid raw material supply line and the injector respectively have an inner diameter of about ⅛ inches.

9. The apparatus according to claim 1, wherein the liquid raw material supply unit comprises:
a liquid raw material tank for storing the at least one liquid raw material and sending the at least one liquid raw material to the liquid raw material supply line at the pressure of an inactivated gas;
a degasser for separately extracting the inactivated gas from the mixture of the at least one liquid raw material being sent from the liquid raw material tank and the inactivated gas and discharging the inactivated gas to the outside; and
a flow controller for controlling the flow rate of the at least one liquid raw material being separated by the degasser and flowing through the liquid raw material supply line.

10. The apparatus according to claim 1, wherein the injector comprises an injection line.

11. The apparatus according to claim 1, wherein the cleaning module comprises:
an inactivated gas supply unit for supplying an inactivated gas at predetermined pressure;
an inactivated gas supply line allowing the inactivated gas supplied from the inactivated gas supply unit to flow through; and
an LSU valve positioned at the end of the inactivated gas supply line corresponding to the inactivated gas supply unit, the LSU valve for controlling the at least one liquid raw material being supplied from the liquid raw material supply unit or the inactivated gas so as to be selectively supplied to the injector.

12. The apparatus according to claim 11, wherein, when the first reaction gas and the second reaction gas are to be supplied into the reaction chamber, the LSU valve is switched to allow the at least one liquid raw material to flow into the injector; and when the first reaction gas and the second reaction gas are not supplied into the reaction chamber, the LSU valve is switched to allow the inactivated gas to flow into the injector.

13. The apparatus according to claim 11, wherein the LSU valve is a three-way valve so that the at least one liquid raw material and the inactivated gas are selectively supplied through the injector and injected into the reaction gas supply line.

14. A method for cleaning an injector included in an apparatus for chemical vapor deposition, comprising:
loading a wafer inside a reaction chamber;
forming a thin film of a predetermined thickness on the wafer, by supplying a first reaction gas and a second reaction gas into the reaction chamber while pumping air present inside the reaction chamber;
stopping the supply of the first reaction gas and the second reaction gas and unloading the wafer to the outside of the reaction chamber after forming the thin film of the predetermined thickness on the wafer;
determining the number of the wafers on which the thin film is formed inside the reaction chamber; and
cleaning an injector, by supplying a purge gas into the reaction chamber and supplying an inactivated gas into the injector which injects at least one liquid raw material used as the second reaction gas supplied into the reaction chamber after the wafers on which the thin film is formed reach a predetermined number.
